(19) United States
(12) Patent Application Publication
(10) Pub. No.: US 2021/0298190 A1
(43) Pub. Date: Sep. 23, 2021

(54) Computing, Controlling Device: Intercheangable, Programmable, Pluggable with integral Controller and Radio

(71) Applicants: Belinda A. Castillo-Beyerlein, Albuquerque, NM (US); Roger Eugene Wiegel, Rio Rancho, MN (US)

(72) Inventors: Belinda Ann Beyerlein, Albuquerque, NM (US); Roger Eugene Wiegel, Rio Rancho, NM (US)

(21) Appl. No.: 16/873,339

(22) Filed: Mar. 18, 2020

(51) Int. Cl. H05K 7/14; H05K 5/00; H05K 5/02

(52) U.S. Cl. CPC H05K 7/1481; H05K 5/0256; H05K 5/0086

(57) ABSTRACT

This Device is a small “Container” which holds a general-purpose programmable computing device (processor), interface electronics, a radio and a “Connector”. The Container plugs into an “Equipment” which is to be controlled, monitored or tested. Equipment is any tool, apparatus, machine, or process which requires a controlling function.

A single “Container” design has electronics which interface with a variety of connected - similar or different—equipments. Interface signals are pre-assigned to unique pins on the Connector. Different equipment then employ the unique signals as needed. Software senses and identifies attached equipment, selects, and runs the appropriate pre-installed application. A subset of the electronics is active for each unique equipment interface. Different equipments use both common and unique pins as needed. Modifications Hardware/software modifications are not needed for different equipment—a “Plug and Play” device.

The radio is used for remote monitoring, software updates and status checks.

### BACKGROUND OF THE INVENTION

This invention applies to the fields of electronics, programmable controllers, computers and wireless usage. It is a small, self-contained, portable, interchangeable, programmable electronic device which plugs in to or connects with a separate controlled device. It has a wireless/radio interface. It is not limited to any particular environment, specification, package or enclosure configuration.

Specific documents/components which are useful to the invention, or are referenced as potentially being used in or part of the invention—but are NOT essential to the invention—include:

Wireless Microprocessor: Texas Instruments Device: CC2652RB—SimpleLink™ Arm® Cortex®-M4F multiprotocol 2.4 GHz crystal-less BAW wireless
is typical of a small but powerful and versatile processor—with wireless capabilities. Edge connector for a Printed Wiring Board: specified as type DIN 41612
a very large family of connectors

Arduino Microprocessor; A common processor with input/output pins, wireless connectivity, programmable. The Arduino “NANO” is typical of this class of electronics. Wireless—Bluetooth—receiver/transmitter device: The Arduino Nano works with a component—the HC05 Bluetooth module.

Very compact, provides bluetooth wireless connectivity to the Arduino.

These components are identified as being part of a small and easily-constructed version of the invention. Constructed on a small printed wiring board, they demonstrate all the features of the claims for this invention: small and compact; programmable processor; wireless interface; a physical connector; and an assembly that is portable, pluggable and interchangeable.

### SUMMARY OF THE INVENTION

### Computing, Controlling Device

This invention provides a compact, portable, programmable controller device—the “enclosure”—which is inserted—or plugged into—into a “receiver”—a part of an equipment to be controlled or monitored. The “enclosure” is a box, package, or container—of appropriate size, shape and form factor for a particular application, containing electronic circuitry and an electrical interface means—a ‘connector’. The enclosure—via the connector—interfaces with a mating connector in a receiver which is a part of a larger equipment.

The “equipment” remains unspecified. It is any electrical, electro-mechanical, or electronic device, mechanism, machine, structure or construct which must, can or might require, or be improved by, a computational means for control, monitoring, testing or similar use. The “equipment” includes a fixed or integral “receiver” assembly into which an “enclosure ” can be inserted. The enclosure may be nothing more than an accessible mating connector.

The “enclosure” holds an assembly consisting of a wireless interface (radio), a programmable computing device (‘computer’), interfacing electronics, a unique “interconnecting component”—or simply, a physical connector—and an optional battery. The enclosure is simply plugged into a receiver socket in an equipment, through which the computing device in the “enclosure” can communicate with and control said equipment.

The “interconnecting component”—the connector—is a defining part of the invention. This is a means by which the ‘computer’ in the enclosure communicates with the connected equipment. The typical realization would be the use of a physical multi-contact (pin), plug-in connector. A mating connector would be located in the ‘receiver’. Alternate connections between the “enclosure” and the “receiver” might include fiber optics, serial data, or a wireless means.

The object of this patent is that the controlling function is easily separable from the controlled function or equipment—by simply unplugging the enclosure component and inserting a replacement. This provides a simple means of upgrading the controlling electronics; temporarily substituting a testing and diagnostic ‘enclosure’; or simply replacing a malfunctioning enclosure.

The components, construction, application of the enclosure/receiver are not specified as they will vary for applications and usage.

### BRIEF DESCRIPTION OF THE DRAWINGS

FIG. 1: The three major components of the invention: Container and Enclosure with Connector

FIG. 2: Detail of a mockup of invention: small box with connector and electronics PWB

FIG. 3: Detail of mated components: Receiver installed in and connected with Enclosure

### A BASIC EXAMPLE OF CONSTRUCTION

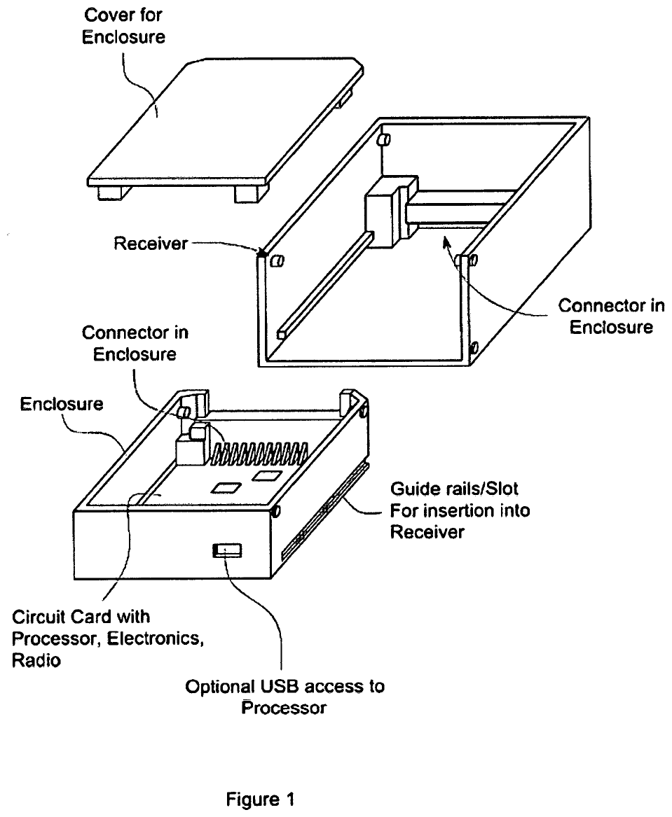

### FIG. 1

The drawing—FIG. 1—illustrates the three basic components of this invention. An “enclosure” component contains electronics connected to a ‘connector’ which is mounted on a part of the enclosure. The ‘enclosure’ depicted is then inserted into a ‘receiver’ component which has a mating connector matching the enclosure connector. The receiver is an integral part of an equipment—a machine, device, assembly or component of a larger system to be controlled, tested or monitored by the electronics contained in the enclosure.

In this particular, unique illustration of a realization of the invention, the enclosure has a ‘handle’ to assist in removal from the receiver; a machined groove to align the enclosure with the receiver, and a common USB connector to facilitate communication with the processor located within the enclosure.

The equipment is any electronic, electro-mechanical or other mechanisms with electrical means to be controlled and/or monitored by the electronics contained in the enclosure.

The receiver is depicted as a container or box in this realization. In practice, the receiver would be an integral part or component of an equipment which is being controlled and monitored by the processor and electronics contained in the enclosure.

The connector on the enclosure mates with the connector contained in or on the receiver assembly. This receiver assembly may be in a separate container or box; or it may be simply a mating connector conveniently mounted in the equipment to be controlled. The assignment of electric and electronic signals to connector pins is a part of this invention. One set of connector pins would contain signals common to all the different equipment to be controlled, such as power, ground and common signals. Other sets of pins would be designated for signals unique to each equipment to be controlled. A third (small) set of pins could be defined as coding to identify what equipment is connected. Electronics and software contained in the enclosure would then select and process only the signals needed with the identified equipment.

Application and Advantages

Within the “enclosure” are unique electronics to properly interface the computing element with the elements of the connected “equipment”. These components are unique to any particular application.

A particular “enclosure” can be adapted to different equipment by proper design of the internal interfaces and by assigning specific signal inputs and outputs to specific or designated pins on a connector. In this manner, one equipment might use several unique signals (pins on the connector) for its' control; and another—different—equipment could use a different set of signals (pins on the connector) for its' control. This enables a particular “enclosure ” design to be employed in different enclosures. The software could be different in the same physical enclosure to effect control of the different equipment.

In use, a particular “enclosure” design would be produced in quantity—all identical. The internal processor would be programmed—via the wireless link—for the intended final use. This programming would use signals from a subset of connector pins. For an entirely different application, the processor would receive different programming. This would, in turn, employ a different subset of signal pins to accomplish a different purpose in a different equipment. Some of the pins on the connector could be used to encode the application for the processor. Or different mechanical keying on the enclosure would insure insertion into only a compatible equipment.

Any size, style or type of connector may be utilized, with any number of connector pins. Each unique pin would then be identified as carrying a particular signal. For example, pin 20 on the connector might be specified as a power input pin; pin 21 specified as a digital output, pin 22 an analog input, etc. Pin definitions and signal assignment to pins on the connector is arbitrary and is the result of the particular design and requirements. Receiver/equipment connector pins would then be selected to match the requirements of the equipment operation.

### DETAILED DESCRIPTION OF THE INVENTION

### How to Build One

The invention has two components—the ‘receiver’ which is built into an (arbitrary) “equipment”, and the ‘enclosure’ which is a transportable (hand-carried) box. The two parts are joined by a multi-pin connector. (The invention is not limited to a physical multi-pin connector; it could employ an optical coupling or other non-physical contacting means.)

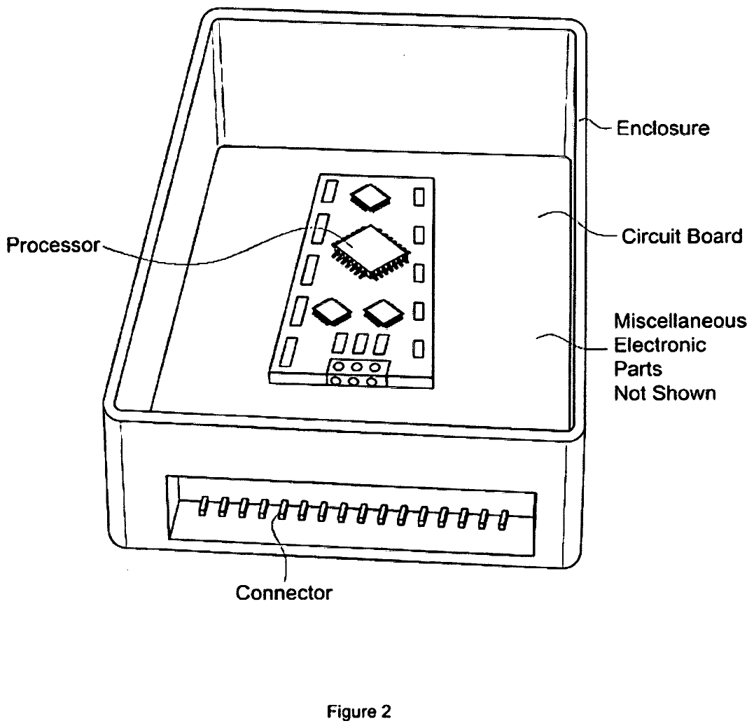

### FIG. 2: Description

An “Enclosure” can be any type of containment means—size, shape, material, construction—which meets the requirements of a particular application. FIG. 2 illustrates this, showing a small plastic container which holds a printed wiring board with a microcomputer subassembly and a connector. This is a life-size mock-up or model, and demonstrates that the claims of this invention are easily-realized in a working model. The microcomputer—in this case—is an Arduino Nano—a very common and available component; the connector is one of many connector types which could be used; and the printed wiring board has space available for a radio component plus several integrated circuits for interfacing between the microcomputer and the external world via the connector. For a high-volume product, everything could be miniaturized onto a very small electronics circuit board.

Making the invention: The invention can be constructed from readily available “off-the-shelf” electrical and electronic components, which are selected, designed, procured and assembled using common industry procedures and practices.

The physical enclosure itself is constructed of materials and processes appropriate to the application environment—plastic or metal or other suitable material(s). Internally, it holds the electronic components identified below, plus the interface connector. It has any mounting and structural support needed, and possibly guide rails and retaining devices—as required for the specific application. An external antenna for the internal wireless transmitter/receiver can be attached to the enclosure if needed.

Inside the enclosure, there would be: a printed wiring board (PWB) to hold and interconnect all the circuitry, and connect with the interface connector. Circuitry will include:

a wireless (radio) interface of appropriate specification (Bluetooth, Zigbee, 5G, telephone bands, satellites radio etc)—no limitations. This enables communication with an external, local or remote source to facilitate uploading and downloading of data;

a programmable computer of appropriate capability (examples: a simple Arduino assembly, an off-the-shelf processor such as the Texas Instruments CC2652RB; or a custom design; all with necessary supporting operational circuitry;

electronics to enable the computer to interface with—receive, drive, adjust, collect, and distribute—signals required by the equipment to be controlled;

a connector of appropriate type, size, capability and pin count to physically and electrically mate with the electronics within the equipment.

All methods and means of constructing the “enclosure ” and the “receiver” are common, standard-practice in industry. No special or unique skills or processes are needed. (A version can be easily-built at home by a person with minimal skills in electronic-design and assembly.)

We note that as the level of capability and complexity of microcircuits continues to increase, the entire electronic circuitry could be integrated into a single chip package—perhaps the size of an ordinary “thumb drive”. This configuration also embodies the claim(s) of this patent.

The receiver is simply a holding and restraining mechanism to enable the enclosure to connect or mate with the mating connector mounted in the equipment. Its' construction is in accordance with the specifications and requirements for the equipment.

The Connector:

The “connector” provides a standardized electrical interface between the ‘enclosure’ and the ‘receiver’—contained in and interconnected with the equipment.

The purpose of this patent is to define an “enclosure ” which can be programmed for and used with different “equipment”. These equipment may have significantly different electrical interfaces. This interchangeability is effected by assigning specific electrical signals to specific pins on the connector which is part of the particular “enclosure ” design.

Each pin's signal is specified per the system design requirements. A ‘master connector configuration’ is established at system design. This determines what types of input/output signals are needed, how many of each type, specifications for each; and finally to which connector pin each signal is to be routed. This defines the “standard connector” for a particular enclosure. Then interface electronics are designed for each signal in order to connect with the processor/computer within the enclosure. Software can then be developed using the I/O (Input/Output) signals as specified.

### Example

Assume there are three similar, but different “equipment” (for example: air handling units of different capacity). Interface signals (logic, analog, digital, power, etc) would be specified for a “receiver” for each “equipment”. Specific signals are assigned to specific “connector” pins. In our example, let us assume each air handler employs 10 signals that are identical to all 3 equipment, and each air handler has 5 signals which are unique to each unit. So that would mean there are (10+3*5=15) or 25 different signals assigned to the “enclosure” connector, each on a unique pin. There could be 3 additional pins used for identifying, or coding for, the specific air handler connected. Ten (10) signals would not be used in any one of the air-conditioning units.

The circuitry in the enclosure would then connect and adapt the processor I/O to the signals to and from the various air handler equipments. The processor is programmed with the software to operate any of the three units (or for just one unit). When the enclosure is plugged in—connected to—an air-handler equipment, the coding pins would identify the specific air-conditioner to the software; the I/O pins would be active for that unit and the software would, in turn, control and monitor that specific type of equipment. The unused pins would be ignored.

The resulting specific “enclosure” could be simply removed from one type of equipment (air handler) and connected to a different type, and it would operate without change. The interface signals are all accounted for, the software would recognize the different equipments and appropriate software would be enabled.

In this manner, it is demonstrated that a single, unique ‘enclosure’ would be fully functional and interchangeable between different “equipment”. How adaptable an enclosure might be is limited by the number of pins on a connector and/or by the types of signals utilized and/or the complexity of the interface electronics and software needed to interface the processor to the equipment to be controlled, monitored or tested.

How to Use the Invention

The “enclosure ” holds a general purpose processing element or computer which can be programmed via the wireless (radio) interface or by a second, physical connector (such as a USB connector). The program is whatever is required to operate and interface with the “equipment”. The enclosure is then transported to the equipment location and inserted into the “receiver”. The enclosure electronics is powered by the equipment, and proceeds to control and monitor the processes performed by the equipment. The enclosure processor can be programmed to monitor the equipment and can report status to a remote location via the wireless interface. The processor can be reprogrammed (a software update) while the enclosure is installed in the receiver via the wireless connection.

An enclosure would be designed to mate and operate with potentially several to many different equipment. It is built and programmed at a central location, transported to the remote location where the mating equipment is located, simply plugged into the mating receiver and the equipment activated. It would then report status to a local (notebook) computer—or possibly to a remote, central processing station to monitor operation of the equipment.

Maintenance

If the ‘enclosure’ is suspected of having a fault, it is easily replaced—simply unplug, remove, and insert a new or spare enclosure properly configured. The (service person) can quickly tell if the “enclosure ” was the problem. It can then be shipped to a central facility for repair.

The ‘equipment’ can be tested by built in software in the operational ‘enclosure’, or a special ‘maintenance enclosure’ could easily temporarily replace the operational enclosure to diagnose the connected equipment. The wireless (radio) could connect to a maintenance facility—local or remotely located—for diagnostics and repair instructions.

### DETAILED DESCRIPTION OF THE INVENTION

The invention provides a means for controlling, testing, maintaining and updating systems of any size, which require a controlling—computer—for operation.

For example, an air-handler system could be controlled from such a device. When diagnostics or maintenance is needed, the installed controlling device (enclosure) would simply be removed and replaced with an identical device containing diagnostics programs to aid in troubleshooting and repair.

The wireless—radio—connection provides a means of communication with the processor in the device. This is used for

a) updating or reprogramming the installed computing device;

b) communicating with real-time events/data gathered by the device—all to a remote location.

c) communicating with a nearby system—for real-time (local) testing and monitoring.

The device can be powered by any convenient means—use of a local self-contained battery or by connecting into the controlled equipment's power system.

The parts and components employed in the construction and realization of this device are not specified for any particular usage. One realization could be a low cost consumer configuration—in which the entire circuitry might be realized as a single integrated component with a simple connector and interface. Another could be an extremely ruggedized (MIL_SPEC) version with components and packaging of necessary quality.

The device's connector is standardized, in the sense that the physical configuration is identical on all devices of a particular design, with signal inputs and outputs assigned to specific pins on the connector. With specific, identified signal pins, the device can be connected to (plugged in to) equipment of different designs or configurations by assigning signals to and from the equipment to specific pinouts. For example, if a particular pin on the connector is defined as an analog input pin, it is connected in an equipment with an analog output and is not used in another equipment not needing such a signal. Software—programming—of the device then fixes the operation and usage of the various pinouts.

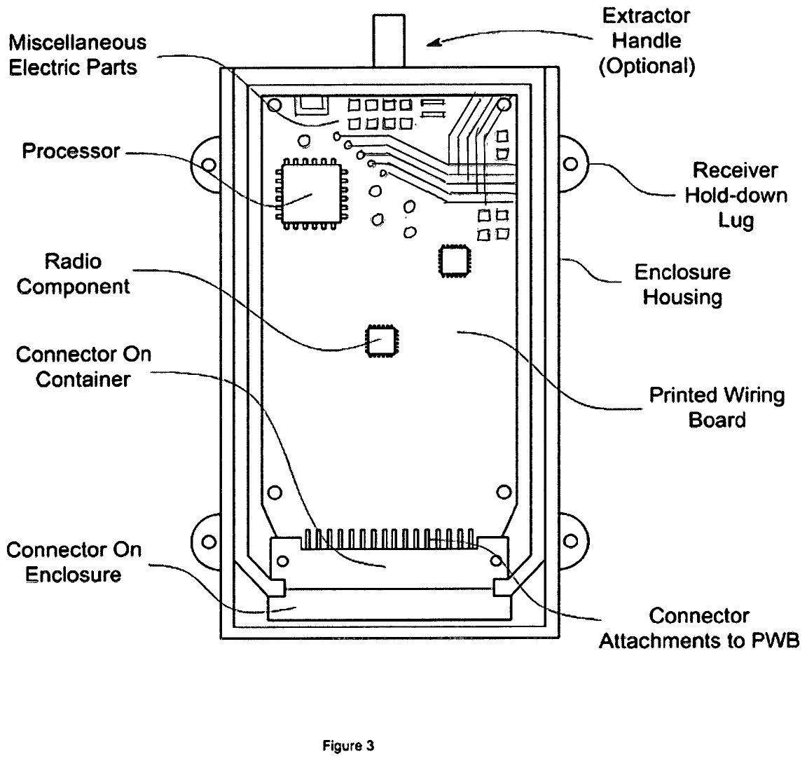

FIG. 3 shows the two components of FIG. 1 assembled and mated. The “Enclosure” is built to hold the circuit card (in color) and mount the connector. In this illustration, the enclosure is a metal container with a removable lid. The enclosure slides into the “Receiver” until the connectors mate. There are four small protrusions—or feet—on the receiver so it can be attached to an equipment. And there is a small extension on the enclosure so it can be grasped and removed. The enclosure can be constructed of metal, plastic or other material. The mating connector which is part of and attached to the enclosure would be connected directly to a printed wiring board or to a wire bundle.

In all applications, the components are designed and constructed to meet the performance requirements of the project. A separate, formal “receiver” is not a necessary component; the matching, mating connector is simply a component of the equipment.

I: This device solves many of the cost problems encountered in the design of a system or family of similar “equipments”, by utilizing a single, modular, compact, easily replaceable “enclosure ” which can be used in a variety of applications to do the computational operations: control/test/maintenance. The development of a single Device (or “enclosure”) will eliminate many of these non-recurring costs as well as reduce support and maintenance costs.
The computational-processing functions are moved into the device so that a common processor function is available for use across a range of I/O's.
This is a single piece, hand-held enclosure with communication, processing, interfacing and interconnecting capabilities able to communicate with, control and monitor a wide variety of equipments in all environments, including but not limited to: aerospace, security and safety, health, entertainment, medical, industrial, consumer, military and space.

II: The use of the Connector component as part of this invention involves the assignment of specific electrical signals to specific pins on the connector, so as to create a universal set of signals which can be utilized by a variety of equipment. In any given realization of this invention, specific signals are pre-assigned to specific pins on an enclosure's connector. Different equipment then connect their necessary signals to the connector pins needed for operation, leaving unused pins blank. Programming of the processor can be different for different applications of a particular enclosure, but the circuitry will be identical. Different pins on the connector would be in use in different applications. No specific connector is specified or implied. The pre-assignment of signals used in any given application and their selection and use by host equipment is claimed.
